(19) United States
(12) Patent Application Publication
(10) Pub. No.: US 2023/0225105 A1
(43) Pub. Date: Jul. 13, 2023

(54) SEMICONDUCTOR MEMORY DEVICE

(71) Applicant: Unisantis Electronics Singapore Pte. Ltd., Singapore (SG)

(72) Inventors: Riichiro SHIROTA, Hsinchu City (TW); Koji SAKUI, Tokyo (JP); Nozomu HARADA, Tokyo (JP)

(21) Appl. No.: 18/151,973

(22) Filed: Jan. 9, 2023

(30) Foreign Application Priority Data
Jan. 11, 2022 (WO) PCT/JP2022/000490

(51) Int. Cl. H10B 12/00

(52) U.S. Cl. CPC H10B 12/20

(57) ABSTRACT

An N⁺ layer 21 connected to a source line SL at both ends of Si pillars 23a to 23d standing in a vertical direction; N⁺ layers 30a and 30b connected to a bit line BL1; N⁺ layers 30c and 30d connected to a bit line BL2; the Si pillars 23a to 23d connected to the N+ layer 21; gate insulating layers 27a to 27d surrounding the Si pillars 23a to 23d; first gate conductor layers 28a and 28b surrounding the gate insulating layers 27a t 27d and connected to plate lines PL1 and PL2; and second gate conductor layers 29a and 29b connected to word lines WL1 and WL2 are disposed on a substrate 1. The Si pillars 23a and 23c have sections partially overlap each other in perspective view of the sections along line X1-X1′ and line X2-X2′, and the same applies to the Si pillars 23b and 23d.

### CROSS-REFERENCE TO RELATED APPLICATIONS

This application claims priority to PCT/JP2022/000490, filed Jan. 11, 2022, the entire content of which is incorporated herein by reference.

### BACKGROUND OF THE INVENTION

### 1. Field of the Invention

The present invention relates to a semiconductor memory device.

### 2. Description of the Related Art

In recent years, higher integration and higher performance of memory elements have been demanded in the development of the large scale integration (LSI) technology.

In a typical planar metal oxide semiconductor (MOS) transistor, a channel extends in a horizontal direction along an upper surface of a semiconductor substrate. In contrast, in a surrounding gate transistor (SGT), a channel extends in a vertical direction with respect to an upper surface of a semiconductor substrate (see, for example, Japanese Unexamined Patent Application Publication No. 2-188966; and Hiroshi Takato, Kazumasa Sunouchi, Naoko Okabe, Akihiro Nitayama, Katsuhiko Hieda, Fumio Horiguchi, and Fujio Masuoka: IEEE Transaction on Electron Devices, Vol. 38, No. 3, pp. 573-578 (1991)). Thus, compared with the planar MOS transistor, the SGT is capable of increasing the density of a semiconductor device. With use of the SGT as a selection transistor, higher integration can be achieved in a dynamic random access memory (DRAM) to which a capacitor is connected (see, for example, H. Chung, H. Kim, H. Kim, K. Kim, S. Kim, K. Song, J. Kim, Y. C. Oh, Y. Hwang, H. Hong, G. Jin, and C. Chung: “4F² DRAM Cell with Vertical Pillar Transistor (VPT)”, 2011 Proceeding of the European Solid-State Device Research Conference, (2011)), a phase change memory (PCM) to which a resistance change element is connected (see, for example, H. S. Philip Wong, S. Raoux, S. Kim, Jiale Liang, J. R. Reifenberg, B. Rajendran, M. Asheghi and K. E. Goodson: “Phase Change Memory”, Proceeding of IEEE, Vol. 98, No. 12, December, pp. 2201-2227 (2010)), a resistive random access memory (RRAM) (see, for example, K. Tsunoda, K. Kinoshita, H. Noshiro, Y. Yamazaki, T. Iizuka, Y. Ito, A. Takahashi, A. Okano, Y. Sato, T. Fukano, M. Aoki, and Y. Sugiyama: “Low Power and High Speed Switching of Ti-doped NiO ReRAM under the Unipolar Voltage Source of less than 3 V”, IEDM (2007)), a magneto-resistive random access memory (MRAM) in which a resistance is changed by changing the orientation of a magnetic spin by using a current (see, for example, W. Kang, L. Zhang, J. Klein, Y. Zhang, D. Ravelosona, and W. Zhao: “Reconfigurable Codesign of STT-MRAM Under Process Variations in Deeply Scaled Technology”, IEEE Transactions on Electron Devices, pp. 1-9 (2015)), and so forth. In addition, there is a capacitorless DRAM memory cell constituted by a single MOS transistor (see, for example, J. Wan, L. Rojer, A. Zaslaysky, and S. Critoloveanu: “A Compact Capacitor-Less High-Speed DRAM Using Field Effect-Controlled Charge Regeneration”, Electron Device Letters, Vol. 35, No. 2, pp. 179-181 (2012)). The present application relates to a dynamic flash memory that does not include a resistance change element or a capacitor and that can be constituted by a MOS transistor alone.

FIGS. 10A to 10D illustrate a write operation of the above-described capacitorless DRAM memory cell constituted by a single MOS transistor, FIGS. 11A and 11B illustrate a problem in the operation, and FIGS. 12A to 12C illustrate a read operation (see J. Wan, L. Rojer, A. Zaslaysky, and S. Critoloveanu: “A Compact Capacitor-Less High-Speed DRAM Using Field Effect-Controlled Charge Regeneration”, Electron Device Letters, Vol. 35, No. 2, pp. 179-181 (2012); T. Ohsawa, K. Fujita, T. Higashi, Y. Iwata, T. Kajiyama, Y. Asao, and K. Sunouchi: “Memory design using a one-transistor gain cell on SOI”, IEEE JSSC, vol. 37, No. 11, pp. 1510-1522 (2002); T. Shino, N. Kusunoki, T. Higashi, T. Ohsawa, K. Fujita, K. Hatsuda, N. Ikumi, F. Matsuoka, Y. Kajitani, R. Fukuda, Y. Watanabe, Y. Minami, A. Sakamoto, J. Nishimura, H. Nakajima, M. Morikado, K. Inoh, T. Hamamoto, and A. Nitayama: “Floating Body RAM Technology and its Scalability to 32 nm Node and Beyond”, IEEE IEDM (2006); and E. Yoshida and T. Tanaka: “A Design of Capacitorless 1T-DRAM Cell Using Gate-Induced Drain-Leakage (GIDL) Current for Low-Power and High-Speed Embedded Memory”, IEEE IEDM (2003)).

FIGS. 10A to 10D illustrate a write operation of the DRAM memory cell. FIG. 10A illustrates a “1” write state. The memory cell herein is formed on a silicon on insulator (SOI) substrate 100 and is constituted by a source N⁺ layer 103 connected to a source line SL (hereinafter, a semiconductor region containing donor impurities at high concentration will be referred to as an “N⁺ layer”), a drain N⁺ layer 104 connected to a bit line BL, a gate conductive layer 105 connected to a word line WL, and a floating body 102 of a MOS transistor 110a. The DRAM memory cell does not have a capacitor and is constituted by the single MOS transistor 110a. A SiO₂ layer 101 of the SOI substrate 100 is immediately under the floating body 102 and is in contact with the floating body 102. To write “1” in the memory cell constituted by the single MOS transistor 110a, the MOS transistor 110a is operated in a saturation region. That is, an electron channel 107 extending from the source N⁺layer 103 has a pinch-off point 108 and does not reach the drain N⁺ layer 104 connected to the bit line BL. When the MOS transistor 110a is operated such that the bit line BL connected to the drain N⁺ layer 104 and the word line WL connected to the gate conductive layer 105 are both at a high voltage and that the gate voltage is about ½ of the drain voltage, the electric field strength becomes maximum at the pinch-off point 108 near the drain N⁺ layer 104. As a result, accelerated electrons flowing from the source N⁺ layer 103 toward the drain N⁺ layer 104 collide with a Si lattice, and the kinetic energy lost at the time generates electron-hole pairs. Most of the generated electrons (not illustrated) reach the drain N⁺ layer 104. A very small portion of the electrons, which is very hot, jumps over a gate oxide film 109 and reaches the gate conductive layer 105. Holes 106 generated simultaneously charge the floating body 102. In this case, the generated holes contribute as an increment of a majority carrier because the floating body 102 is made of P-type Si. When the floating body 102 is filled with the generated holes 106 and the voltage of the floating body 102 becomes higher than that of the source N⁺ layer 103 by Vb or more, holes further generated are discharged to the source N⁺ layer 103. Vb herein is a built-in voltage of the PN junction between the source N⁺ layer 103 and the floating body 102 as a P layer, and is about 0.7 V. FIG. 10B illustrates a state in which the floating body 102 is charged to saturation with the generated holes 106.

Next, a “0” write operation of a memory cell 110 will be described with reference to FIG. 10C. For a selected common word line WL, there are randomly a memory cell 110a for writing “1” and a memory cell 110b for writing “0”. FIG. 10C illustrates a state of rewriting from a “1” write state to a “0” write state. To write “0”, the voltage of the bit line BL is negatively biased, and the PN junction between the drain N⁺ layer 104 and the floating body 102 as a P layer is forward biased. As a result, the holes 106 generated in the floating body 102 in advance in the previous cycle flow into the drain N⁺ layer 104 connected to the bit line BL. Upon completion of the write operation, two memory cell states are obtained: the memory cell 110a filled with the generated holes 106 (FIG. 10B); and the memory cell 110b from which the generated holes have been discharged (FIG. 10C). The floating body 102 of the memory cell 110a filled with the holes 106 has a potential higher than that of the floating body 102 having no generated holes. Thus, a threshold voltage of the memory cell 110a is lower than a threshold voltage of the memory cell 110b. This state is illustrated in FIG. 10D.

Next, a problem in the operation of the memory cell constituted by the single MOS transistor will be described with reference to FIGS. 11A and 11B. As illustrated in FIG. 11A, a capacitance C_{FB} of the floating body 102 is the sum of a capacitance C_{WL} between the gate connected to the word line and the floating body 102, a junction capacitance C_{SL} of the PN junction between the source N⁺ layer 103 connected to the source line and the floating body 102, and a junction capacitance C_{BL} of the PN junction between the drain N⁺ layer 104 connected to the bit line and the floating body 102, and is expressed as follows.

C_{FB}=C_{WL}+C_{BL}+C_{SL} (1)

Thus, if a word line voltage V_{WL} oscillates at the time of writing, the oscillation affects the voltage of the floating body 102 serving as a storage node (contact point) of the memory cell. This state is illustrated in FIG. 11B. In accordance with an increase in the word line voltage V_{WL} from 0 V to V_{ProgWL} at the time of writing, a voltage V_{FB} of the floating body 102 increases from a voltage V_{FB1} in an initial state before the word line voltage changes to a voltage V_{FB2} due to capacitive coupling with the word line. The amount of voltage change ΔV_{FB} is expressed as follows.

ΔV_{FB}=V_{FB2}−V_{FB1}=C_{WL}/(C_{WL}+C_{BL}+C_{SL})×C_{ProgWL} (2)

Here, the following equation holds, in which β represents a coupling ratio.

β=C_{WL}/(C_{WL}+C_{BL}+C_{SL}) (3)

In such a memory cell, C_{WL} has a high contribution ratio, for example, C_{WL}:C_{BL}:C_{SL}=8:1:1. In this case, 0 equals 0.8. When the word line changes, for example, from 5 V at the time of writing to 0 V after the end of writing, the capacitive coupling between the word line and the floating body 102 causes the floating body 102 to be subjected to oscillation noise of 5 V×β=4 V. This involves a problem that a sufficient potential difference margin is not provided between the “1” potential and the “0” potential of the floating body 102 at the time of writing.

FIGS. 12A to 12C illustrate a read operation. FIG. 12A illustrates a “1” write state, and FIG. 12B illustrates a “0” write state. Actually, however, even if Vb is written in the floating body 102 by “1” writing, the floating body 102 is lowered to a negative bias when the word line returns to 0 V upon completion of writing. When “0” is written, the floating body 102 is further negatively biased, and thus it is impossible to provide a sufficiently large potential difference margin between “1” and “0” at the time of writing. The small operation margin is a major problem of the DRAM memory cell. In addition, there is an issue of increasing the density of the DRAM memory cell.

There are twin-transistor memory elements in which one memory cell is formed in an SOI layer by using two MOS transistors (see, for example, US2008/0137394A1 and US2003/0111681A1). In these elements, an N⁺ layer, which serves as a source or a drain for separating floating body channels of two MOS transistors, is formed in contact with an insulating layer. Since the N⁺ layer is in contact with the insulating layer, the floating body channels of the two MOS transistors are electrically isolated from each other. A group of holes serving as signal charges are accumulated in the floating body channel of one of the transistors. The voltage of the floating body channel in which the holes are accumulated is greatly changed by applying a pulse voltage to the gate electrode of an adjacent MOS transistor in a manner similar to equation (2), as described above. Accordingly, as described with reference to FIGS. 10A to 12C, it is impossible to sufficiently increase the operation margin between “1” and “0” at the time of writing (see, for example, F. Morishita, H. Noda, I. Hayashi, T. Gyohten, M. Oksmoto, T. Ipposhi, S. Maegawa, K. Dosaka, and K. Arimoto: “Capacitorless Twin-Transistor Random Access Memory (TTRAM) on SOI”, IEICE Trans. Electron., Vol. E90-c., No. 4, pp. 765-771 (2007), FIG. 8).

### SUMMARY OF THE INVENTION

A capacitorless single-transistor DRAM (gain cell) serving as a memory device including an SGT has a problem that oscillation of the potential of the word line at the time of reading or writing data is directly transmitted as noise to an SGT body because the capacitive coupling between the word line and the SGT body in a floating state is large. This results in a problem of erroneous reading or erroneous rewriting of stored data, and difficulty in putting a capacitorless single-transistor DRAM (gain cell) into practical use. It is necessary to increase the density of DRAM memory cells in addition to solve the above problems.

To solve the above problems, a semiconductor memory device according to the present invention includes:

a first impurity layer disposed on a substrate;

a first semiconductor pillar and a second semiconductor pillar that are adjacent to each other on the first impurity layer and that stand in a vertical direction with respect to the substrate;

a second impurity layer disposed at a top portion of the first semiconductor pillar, and a third impurity layer disposed at a top portion of the second semiconductor pillar;

a first gate insulating layer surrounding lower side surfaces of the first semiconductor pillar and the second semiconductor pillar, and a second gate insulating layer surrounding upper side surfaces of the first semiconductor pillar and the second semiconductor pillar;

a first gate conductor layer surrounding a side surface of the first gate insulating layer; and

a second gate conductor layer surrounding a side surface of the second gate insulating layer, in which

in plan view, a midpoint of the first semiconductor pillar and a midpoint of the second semiconductor pillar in a first direction are displaced from each other in a second direction orthogonal to the first direction or in the first direction,

a vertical section of the first semiconductor pillar and a vertical section of the second semiconductor pillar in the first direction or the second direction partially overlap each other in perspective view in a vertical section direction,

the semiconductor memory device further includes:
a first conductor layer made of a metal or an alloy and covering a part or an entirety of the second impurity layer at the top portion of the first semiconductor pillar, and a second conductor layer made of a metal or an alloy and covering a part or an entirety of the third impurity layer at the top portion of the second semiconductor pillar;
a first contact hole that is in contact with the first conductor layer in plan view, and a second contact hole that is in contact with the second conductor layer in plan view; and
a first wiring metal layer connected to the first conductor layer via the first contact hole and extending in the second direction, and a second wiring metal layer connected to the second conductor layer via the second contact hole and extending in the second direction,

the second wiring metal layer overlaps a part of the first conductor layer and a part of the second conductor layer in plan view, and

the semiconductor memory device is configured to perform
a data write operation and a data hold operation of holding, in an inside of the first semiconductor pillar and the second semiconductor pillar, holes or electrons generated by an impact ionization phenomenon or a gate-induced drain-leakage current, by applying a voltage to the first impurity layer, the second impurity layer, the third impurity layer, the first gate conductor layer, and the second gate conductor layer, and
a data erase operation of discharging the held holes or electrons from the inside of the first semiconductor pillar and the second semiconductor pillar by applying a voltage to the first impurity layer, the second impurity layer, the third impurity layer, the first gate conductor layer, and the second gate conductor layer (first invention).

In the above-described first invention, the first impurity layer is connected to a source line whereas the second impurity layer and the third impurity layer are connected to a bit line, or

the first impurity layer is connected to the bit line whereas the second impurity layer and the third impurity layer are connected to the source line (second invention).

In the above-described first invention, the first gate conductor layer is connected to a plate line whereas the second gate conductor layer is connected to a word line, or

the first gate conductor layer is connected to the word line whereas the second gate conductor layer is connected to the plate line (third invention).

In the above-described first invention, in semiconductor pillar groups which are in a memory region and each of which includes the first semiconductor pillar and the second semiconductor pillar on the substrate, the first gate conductor layer surrounding the first semiconductor pillar and the second semiconductor pillar is continuous between the semiconductor pillar groups in plan view (fourth invention).

In the above-described first invention, in semiconductor pillar groups which are in a memory region and each of which includes the first semiconductor pillar and the second semiconductor pillar on the substrate, the first gate conductor layer surrounding the first semiconductor pillar and the second semiconductor pillar and the second gate conductor layer surrounding the first semiconductor pillar and the second semiconductor pillar are each continuous between the semiconductor pillar groups in plan view (fifth invention).

In the above-described first invention, the first contact hole has a center point displaced from a center point of the first semiconductor pillar in the first direction and is in contact with the first conductor layer in plan view, and

the second contact hole has a center point displaced from a center point of the second semiconductor pillar in the first direction and is in contact with the second conductor layer in plan view (sixth invention).

In the above-described first invention, in the vertical direction, an upper end of the first contact hole is above an upper end of the second contact hole, and a bottom surface of the first wiring metal layer extending in a horizontal direction is above an upper surface of the second wiring metal layer extending in the horizontal direction (seventh invention).

In the above-described first invention, in the vertical direction, the first wiring metal layer and the second wiring metal layer are at different heights (eighth invention).

In the above-described first invention, the semiconductor memory device further includes one or more third semiconductor pillars each of which has a center point on a first line connecting a center point of the first semiconductor pillar and a center point of the second semiconductor pillar and which are arranged at an equal pitch in a length between the center point of the first semiconductor pillar and the center point of the second semiconductor pillar in plan view, in which

the first gate insulating layer surrounds lower portions of the first semiconductor pillar, the second semiconductor pillar, and the one or more third semiconductor pillars,

the second gate insulating layer surrounds upper portions of the first semiconductor pillar, the second semiconductor pillar, and the one or more third semiconductor pillars,

the first gate conductor layer covers the first gate insulating layer, and

the second gate conductor layer covers the second gate insulating layer (ninth invention).

In the above-described ninth invention, in plan view, two or more block regions, each including the first semiconductor pillar, the second semiconductor pillar, and the one or more third semiconductor pillars, are connected to each other and provided in a direction in which the second gate conductor layer extends, and

in plan view, the first wiring metal layer is disposed above the first conductor layer on the top portion of the first semiconductor pillar and above a third conductor layer on the top portion of the one or more third semiconductor pillars at an end of an adjacent block region (tenth invention).

In the above-described first invention, in plan view, a distance between the second gate conductor layer and a fourth gate conductor layer that is adjacent to the second gate conductor layer and connected to a second word line is larger than a half of a larger one of a thickness of the first gate conductor layer and a thickness of the second gate conductor layer (eleventh invention).

In the above-described first invention, the first impurity layer outside the first semiconductor pillar and the second semiconductor pillar has therein a metal layer or an alloy layer in plan view (twelfth invention).

In the above-described first invention, a first gate capacitance between the first gate conductor layer and the first semiconductor pillar is larger than a second gate capacitance between the second gate conductor layer and the first semiconductor pillar (thirteenth invention).

In the above-described first invention, one or both of the first gate conductor layer and the second gate conductor layer are divided into a plurality of gate conductor layers in the vertical direction, the plurality of gate conductor layers being configured to be driven synchronously or asynchronously (fourteenth invention).

### BRIEF DESCRIPTION OF THE DRAWINGS

FIG. 1 is a structural diagram of a semiconductor-element-including memory device according to a first embodiment;

FIGS. 2A, 2B, and 2C are diagrams for describing an erase operation mechanism of the semiconductor-element-including memory device according to the first embodiment;

FIGS. 3A, 3B, and 3C are diagrams for describing a write operation mechanism of the semiconductor-element-including memory device according to the first embodiment;

FIGS. 4AA, 4AB, and 4AC are diagrams for describing a read operation mechanism of the semiconductor-element-including memory device according to the first embodiment;

FIGS. 4BA, 4BB, 4BC, and 4BD are diagrams for describing a read operation mechanism of the semiconductor-element-including memory device according to the first embodiment;

FIGS. 5A and 5B are diagrams for describing the semiconductor-element-including memory device according to the first embodiment;

FIGS. 6A and 6B are diagrams for describing a semiconductor-element-including memory device according to a second embodiment;

FIGS. 7A and 7B are diagrams for describing a semiconductor-element-including memory device according to a third embodiment;

FIG. 8A is a diagram for describing a semiconductor-element-including memory device according to a fourth embodiment;

FIG. 8B is a diagram for describing the semiconductor-element-including memory device according to the fourth embodiment;

FIG. 9 is a diagram for describing a semiconductor-element-including memory device according to a fifth embodiment;

FIGS. 10A, 10B, 10C, and 10D are diagrams for describing a write operation of a capacitorless DRAM memory cell according to the related art;

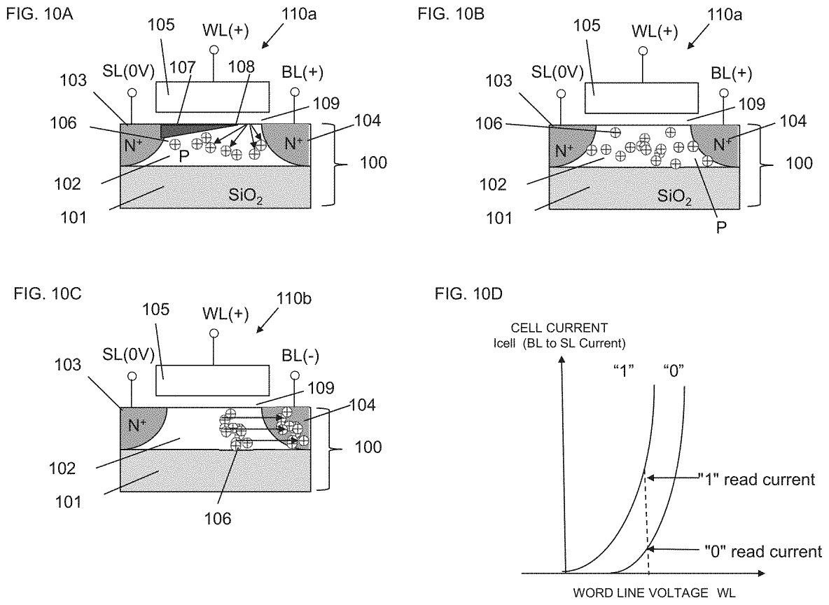

FIGS. 11A and 11B are diagrams for describing a problem in the operation of the capacitorless DRAM memory cell according to the related art; and

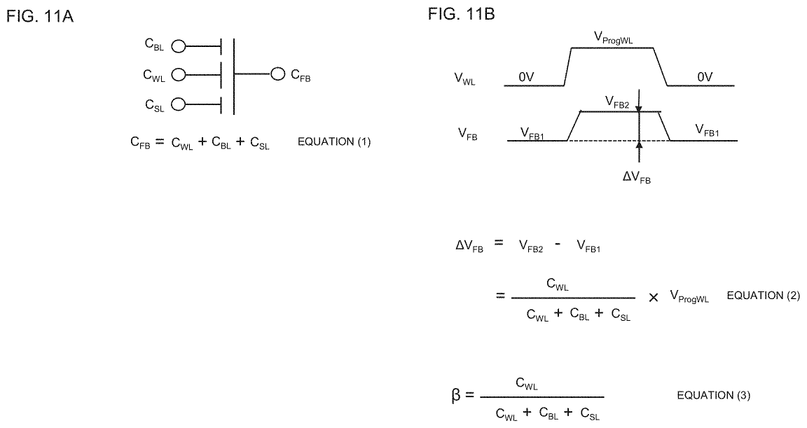

FIGS. 12A, 12B, and 12C are diagrams for describing a read operation of the capacitorless DRAM memory cell according to the related art.

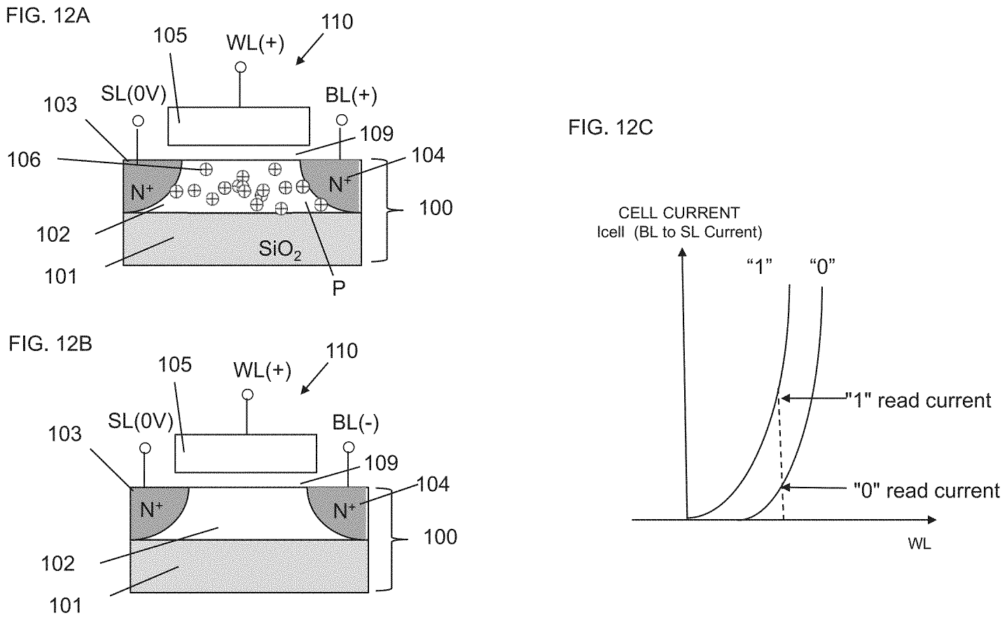

### DESCRIPTION OF THE PREFERRED EMBODIMENTS

Hereinafter, a semiconductor-element-including memory (hereinafter referred to as a dynamic flash memory) device according to the present invention will be described with reference to the drawings.

### First Embodiment

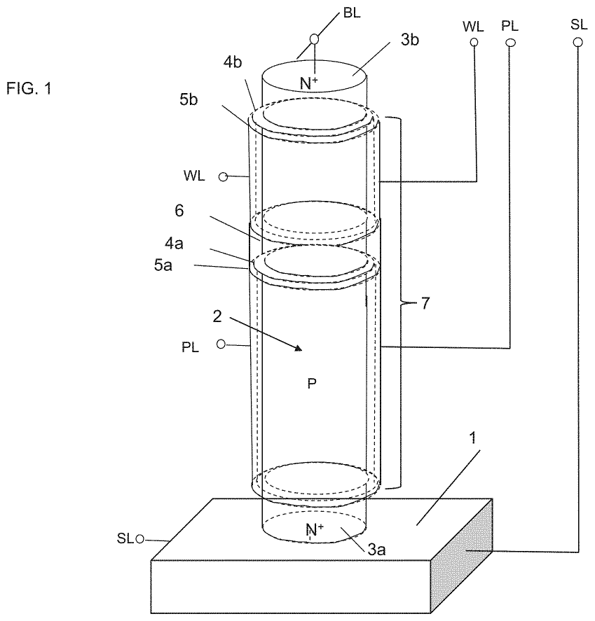

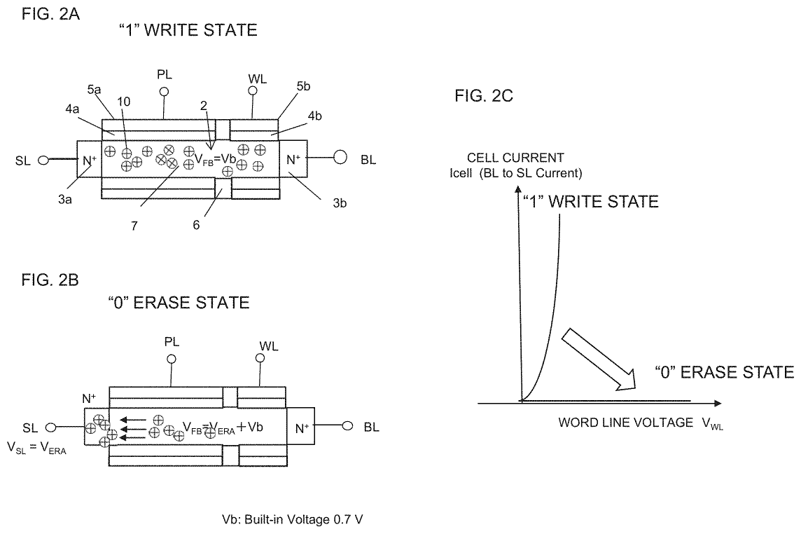

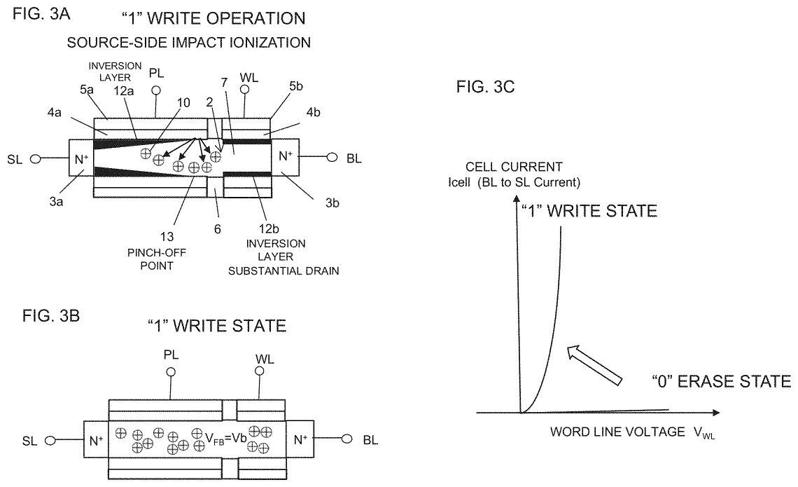

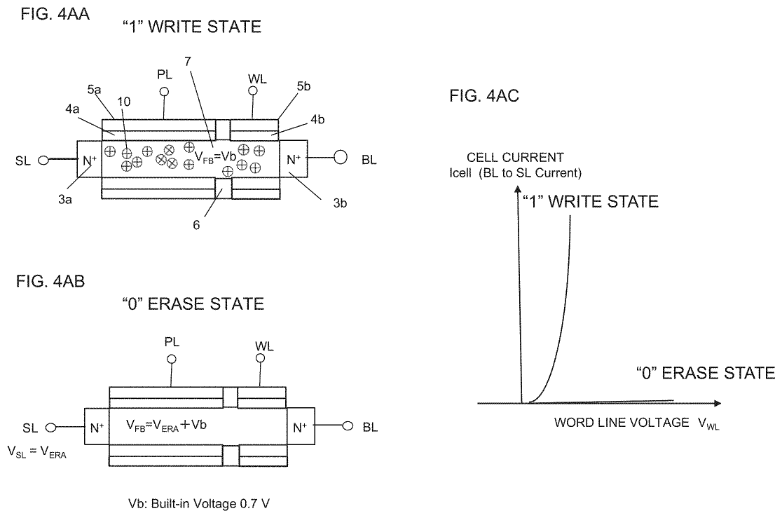

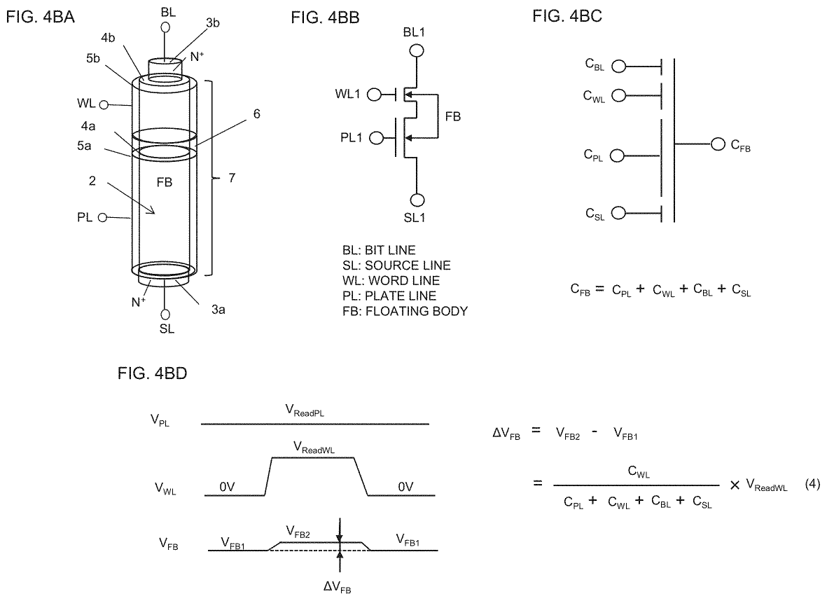

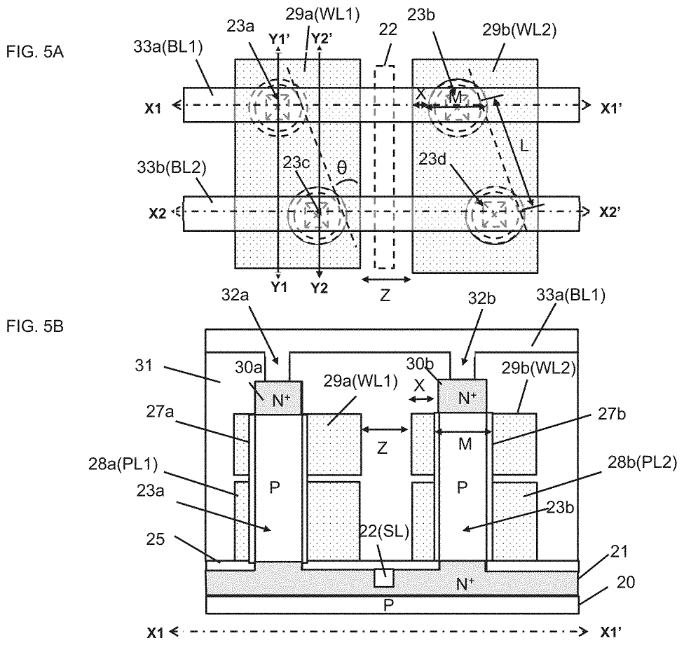

The structure, operation mechanism, and manufacturing method of a dynamic flash memory cell according to a first embodiment of the present invention will be described with reference to FIG. 1 to FIG. 5B. The structure of the dynamic flash memory cell will be described with reference to FIG. 1. A data erase mechanism will be described with reference to FIGS. 2A to 2C, a data write mechanism will be described with reference to FIGS. 3A to 3C, and a data read mechanism will be described with reference to FIGS. 4AA to 4BD. A dynamic flash memory in which memory cells are arranged two-dimensionally will be described with reference to FIGS. 5A and 5B.

FIG. 1 illustrates the structure of the dynamic flash memory cell according to the first embodiment of the present invention. At lower and upper positions in a silicon semiconductor pillar 2 (an example of “first semiconductor pillar” in the claims, hereinafter a silicon semiconductor pillar will be referred to as a “Si pillar”) having a conductivity type of P type or i type (intrinsic type) and formed on a substrate 1 (an example of “substrate” in the claims), an N⁺ layer 3a (an example of “first impurity layer” in the claims) and an N⁺ layer 3b (an example of “second impurity layer” in the claims) are formed, one of which serves as a source and the other of which servers as a drain. The portion of the Si pillar 2 between the N⁺ layers 3a and 3b serving as the source and drain is a channel region 7. A first gate insulating layer 4a (an example of “first gate insulating layer” in the claims) and a second gate insulating layer 4b (an example of “second gate insulating layer” in the claims) are formed so as to surround the channel region 7. The first gate insulating layer 4a and the second gate insulating layer 4b are respectively in contact with or close to the N⁺ layers 3a and 3b serving as the source and drain. A first gate conductor layer 5a (an example of “first gate conductor layer” in the claims) and a second gate conductor layer 5b (an example of “second gate conductor layer” in the claims) are formed so as to respectively surround the first gate insulating layer 4a and the second gate insulating layer 4b. The first gate conductor layer 5a and the second gate conductor layer 5b are isolated from each other by an insulating layer 6. Accordingly, the dynamic flash memory cell composed of the N⁺ layers 3a and 3b serving as the source and drain, the channel region 7, the first gate insulating layer 4a, the second gate insulating layer 4b, the first gate conductor layer 5a, and the second gate conductor layer 5b is formed. The N⁺ layer 3a serving as the source is connected to a source line SL (an example of “source line” in the claims), the N⁺ layer 3b serving as the drain is connected to a bit line BL (an example of “bit line” in the claims), the first gate conductor layer 5a is connected to a plate line PL (an example of “plate line” in the claims), and the second gate conductor layer 5b is connected to a word line WL (an example of “word line” in the claims). In a desired structure, the gate capacitance of the first gate conductor layer 5a connected to the plate line PL is larger than the gate capacitance of the second gate conductor layer 5b connected to the word line WL.

An erase operation mechanism will be described with reference to FIGS. 2A to 2C. The channel region 7 between the N⁺ layers 3a and 3b is electrically isolated from the substrate 1 and serves as a floating body. FIG. 2A illustrates a state in which a hole group 10 generated by impact ionization in the previous cycle is stored in the channel region 7 before an erase operation. As illustrated in FIG. 2B, the voltage of the source line SL is set to a negative voltage V_{ERA} at the time of an erase operation. Here, V_{ERA} is −3 V, for example. As a result, the PN junction between the channel region 7 and the N⁺ layer 3a serving as the source connected to the source line SL is forward biased, regardless of the value of an initial potential of the channel region 7. As a result, the hole group 10 generated by impact ionization in the previous cycle and stored in the channel region 7 is drawn into the N⁺ layer 3a serving as the source, and a potential V_{FB} of the channel region 7 becomes V_{ERA}+Vb. Here, Vb is a built-in voltage of the PN junction and is about 0.7 V. Thus, when V_{ERA}=−3 V holds, the potential of the channel region 7 is −2.3 V. This value corresponds to the potential state of the channel region 7 in an erase state. Thus, when the potential of the channel region 7 of the floating body becomes a negative voltage, the threshold voltage of the N-channel MOS transistor increases due to a substrate bias effect. Accordingly, the threshold voltage of the second gate conductor layer 5b connected to the word line WL increases as illustrated in FIG. 2C. The erase state in the channel region 7 corresponds to logical storage data “0”. The above-described conditions of the voltages applied to the bit line BL, the source line SL, the word line WL, and the plate line PL are examples for performing an erase operation. Other voltage conditions for performing an erase operation may be used.

FIGS. 3A to 3C illustrate a write operation of the dynamic flash memory cell according to the first embodiment of the present invention. As illustrated in FIG. 3A, for example, 0 V is input to the N⁺ layer 3a connected to the source line SL, for example, 3 V is input to the N⁺ layer 3b connected to the bit line BL, for example, 2 V is input to the first gate conductor layer 5a connected to the plate line PL, and for example, 5 V is input to the second gate conductor layer 5b connected to the word line WL. As a result, as illustrated in FIG. 3A, a ring-shaped inversion layer 12a is formed in the channel region 7 on an inner side from the first gate conductor layer 5a connected to the plate line PL, and a first N-channel MOS transistor region including the first gate conductor layer 5a is operated in a saturation region. As a result, a pinch-off point 13 is present in the inversion layer 12a on an inner side from the first gate conductor layer 5a connected to the plate line PL. On the other hand, a second N-channel MOS transistor region including the second gate conductor layer 5b connected to the word line WL is operated in a linear region. As a result, in the channel region 7 on an inner side from the second gate conductor layer 5b connected to the word line WL, a pinch-off point is absent, and an inversion layer 12b is formed over the entire surface. The inversion layer 12b formed over the entire surface on the inner side from the second gate conductor layer 5b connected to the word line WL substantially functions as the drain of the second N-channel MOS transistor region including the second gate conductor layer 5b. As a result, the electric field becomes maximum in the boundary region of the channel region 7 between the first N-channel MOS transistor region including the first gate conductor layer 5a and the second N-channel MOS transistor region including the second gate conductor layer 5b that are connected in series, and an impact ionization phenomenon occurs in this region. This region is a region on the source side when viewed from the second N-channel MOS transistor region including the second gate conductor layer 5b connected to the word line WL, and thus this phenomenon is referred to as a source-side impact ionization phenomenon. The source-side impact ionization phenomenon causes electrons to flow from the N⁺ layer 3a connected to the source line SL toward the N⁺ layer 3b connected to the bit line BL. Accelerated electrons collide with lattice Si atoms, and the kinetic energy thereof generates electron-hole pairs. Some of the generated electrons flow to the first gate conductor layer 5a and the second gate conductor layer 5b, but most of the electrons flow to the N⁺ layer 3b connected to the bit line BL. In writing of “1”, electron-hole pairs may be generated by using a gate-induced drain-leakage (GIDL) current, and a floating body FB may be filled with the generated hole group (see E. Yoshida and T. Tanaka: “A Capacitorless 1T-DRAM Technology Using Gate-Induced Drain-Leakage (GIDL) Current for Low-Power and High-Speed Embedded Memory”, IEEE Transactions on Electron Devices, Vol. 53, No. 4, pp. 692-697, April 2006).

As illustrated in FIG. 3B, the generated hole group 10 is a majority carrier in the channel region 7 and charges the channel region 7 to a positive bias. The N⁺ layer 3a connected to the source line SL is at 0 V, and thus the channel region 7 is charged to the built-in voltage Vb (about 0.7 V) of the PN junction between the N⁺ layer 3a connected to the source line SL and the channel region 7. Upon the channel region 7 being charged to a positive bias, the threshold voltages of the first N-channel MOS transistor region and the second N-channel MOS transistor region are decreased by a substrate bias effect. Accordingly, as illustrated in FIG. 3C, the threshold voltage of the second N-channel MOS transistor connected to the word line WL decreases. The write state of the channel region 7 is assigned to logical storage data “1”.

At the time of the write operation, electron-hole pairs may be generated by an impact ionization phenomenon or a GIDL current in a boundary region between the N⁺ layer 3a and the channel region 7 or in a boundary region between the N⁺ layer 3b and the channel region 7, and the channel region 7 may be charged with the generated hole group 10. The above-described conditions of the voltages applied to the bit line BL, the source line SL, the word line WL, and the plate line PL are examples for performing a write operation. Other operation conditions for performing a write operation may be used. The impact ionization phenomenon may be caused to occur in a part or an entirety of the second N-channel MOS transistor region.

A read operation of the dynamic flash memory cell according to the first embodiment of the present invention and a memory cell structure related thereto will be described with reference to FIGS. 4AA to 4AC and FIGS. 4BA to 4BD. The read operation of the dynamic flash memory cell will be described with reference to FIGS. 4AA to 4AC. As illustrated in FIG. 4AA, upon the channel region 7 being charged to the built-in voltage Vb (about 0.7 V), the threshold voltage of the N-channel MOS transistor is decreased by a substrate bias effect. This state is assigned to logical storage data “1”. As illustrated in FIG. 4AB, when the memory block selected before writing is in an erase state “0” in advance, the channel region 7 is at a floating voltage V_{FB}, which is V_{ERA}+Vb. A write operation causes a write state “1” to be randomly stored. As a result, logical storage data of the logic “0” and “1” is generated for the word line WL. As illustrated in FIG. 4AC, reading is performed by a sense amplifier by using a difference between two threshold voltages for the word line WL.

With reference to FIGS. 4BA to 4BD, a description will be given of the magnitude relationship between the gate capacitances of the first gate conductor layer 5a and the second gate conductor layer 5b at the time of a read operation of the dynamic flash memory cell according to the first embodiment of the present invention, and the operation related thereto. The gate capacitance of the second gate conductor layer 5b connected to the word line WL is desirably designed so as to be smaller than the gate capacitance of the first gate conductor layer 5a connected to the plate line PL. As illustrated in FIG. 4BA, the length in a central-axis direction of the first gate conductor layer 5a connected to the plate line PL is made longer than the length in a central-axis direction of the second gate conductor layer 5b connected to the word line WL, so that the gate capacitance of the second gate conductor layer 5b connected to the word line WL is smaller than the gate capacitance of the first gate conductor layer 5a connected to the plate line PL. FIG. 4BB illustrates an equivalent circuit of one cell of the dynamic flash memory illustrated in FIG. 4BA. FIG. 4BC illustrates a coupling capacitance relationship of the dynamic flash memory. Here, C_{WL} is the capacitance of the second gate conductor layer 5b, C_{PL} is the capacitance of the first gate conductor layer 5a, C_{BL} is the capacitance of the PN junction between the N⁺ layer 3b serving as a drain and the channel region 7, and C_{SL} is the capacitance of the PN junction between the N⁺ layer 3a serving as a source and the channel region 7. As illustrated in FIG. 4BD, when the voltage of the word line WL oscillates, the operation affects the channel region 7 as noise. A potential variation ΔV_{FB} of the channel region 7 at this time is expressed as follows.

ΔV_{FB}=V_{FB2}−V_{FB1}=C_{WL}/(C_{PL}+C_{WL}+C_{BL}+C_{SL})×V_{ReadWL} (4)

Here, V_{ReadWL} is the oscillation potential of the word line WL at the time of reading. As is apparent from equation (4), ΔV_{FB} decreases as the contribution ratio of C_{WL} decreases relative to the total capacitance C_{PL}+C_{WL}+C_{BL}+C_{SL} of the channel region 7. The above-described conditions of the voltages applied to the bit line BL, the source line SL, the word line WL, and the plate line PL are examples for performing a read operation. Other voltage conditions for performing a read operation may be used.

A more detailed structure of the dynamic flash memory according to the present embodiment will be described with reference to FIGS. 5A and 5B. FIG. 5A is a plan view, and FIG. 5B is a vertical sectional view taken along the line X1-X1′ in FIG. 5A. In an actual dynamic flash memory, more memory cells are arranged two-dimensionally.

As illustrated in FIGS. 5A and 5B, an N⁺ layer 21 (an example of “first impurity layer” in the claims) is disposed on a P-layer substrate 20 (an example of “substrate” in the claims). A Si pillar 23a (an example of “first semiconductor pillar” in the claims), a Si pillar 23b, a Si pillar 23c (an example of “second semiconductor pillar” in the claims), and a Si pillar 23d are disposed on the N⁺ layer 21. In plan view, a tungsten (W) layer 22, for example, is disposed in the N⁺ layer 21 between a set of the Si pillars 23a and 23c and a set of the Si pillars 23b and 23d. A SiO₂ layer 25 is disposed on the N⁺ layer 21, in outer periphery portions of the Si pillars 23a to 23d. A gate insulating layer 27a (an example of “first gate insulating layer” in the claims), a gate insulating layer 27b, a gate insulating layer 27c (not illustrated, an example of “first gate insulating layer” in the claims), and a gate insulating layer 27d (not illustrated) surround side surfaces of the Si pillars 23a to 23d, respectively. A first gate conductor layer 28a (an example of “first gate conductor layer” of the claims) and a first gate conductor layer 28b surround lower portions of the gate insulating layers 27a to 27d. The first gate conductor layer 28a surrounds the gate insulating layers 27a and 27c, and the first gate conductor layer 28b surrounds the gate insulating layers 27b and 27d. A second gate conductor layer 29a (an example of “second gate conductor layer” of the claims) and a second gate conductor layer 29b surround upper portions of the gate insulating layers 27a to 27d, and are isolated from the first gate conductor layers 28a and 28b. The second gate conductor layer 29a surrounds the gate insulating layers 27a and 27c, and the second gate conductor layer 29b surrounds the gate insulating layers 27b and 27d. An N⁺ layer 30a (an example of “second impurity layer” in the claims), an N⁺ layer 30b, an N⁺ layer 30c (not illustrated, an example of “third impurity layer” in the claims), and an N⁺ layer 30d (not illustrated) are disposed at top portions of the Si pillars 23a to 23d, respectively. An insulating layer 31 covers the entirety. Contact holes 32a, 32b, 32c, and 32d are disposed on the N⁺ layers 30a to 30d, in the insulating layer 31. A wiring metal layer 33a is connected to the N⁺ layers 30a and 30b via the contact holes 32a and 32b, and a wiring metal layer 33b is connected to the N⁺ layers 30c and 30d via the contact holes 32c and 32d. The first gate conductor layers 28a and 28b and the second gate conductor layers 29a and 29b extend in a direction (an example of “first direction” in the claims) orthogonal to a direction in which the line X1-X1′ and the line X2-X2′ extend (an example of “second direction” in the claims). The W layer 22 is connected to the source line SL (an example of “source line” in the claims), the first gate conductor layer 28a is connected to a first plate line PL1 (an example of “plate line” in the claims), the first gate conductor layer 28b is connected to a second plate line PL2, the second gate conductor layer 29a is connected to a first word line WL1 (an example of “word line” in the claims), the second gate conductor layer 29b is connected to a second word line WL2, the wiring metal layer 33a is connected to a first bit line BL1 (an example of “bit line” in the claims), and the wiring metal layer 33b is connected to a second bit line BL2.

As illustrated in FIG. 5A, the center points of the Si pillars 23a and 23c are displaced from each other in a direction parallel to the line X1-X1′ and the line X2-X2′ in plan view. In plan view, the angle formed by a straight line parallel to the line Y1-Y1′ and a common tangent line of the outer periphery line of the Si pillar 23a and the outer periphery line of the Si pillar 23c is represented by θ. The distance between a contact point between the Si pillar 23a and the common tangent line and a contact point between the Si pillar 23c and the common tangent line is represented by L (in the figure, the distance L is indicated between the Si pillars 23b and 23d for easy viewing). L is the distance between the center points of the Si pillars 23b and 23d. The diameter of each Si pillar is represented by M. On the line X1-X1′, the distance between the outer periphery line of each of the Si pillars 23a and 23b and the outer periphery line of each of the second gate conductor layers 29a and 29b is represented by X. The distance between the second gate conductor layers 29a and 29b on the line X1-X1′ is represented by Z, and a cell area S is expressed by the following equation.

S=L cos θ×(2X+M+L sin θ) (5)

Here, L, X, and M are determined by minimum values, accuracy, and so forth in a process such as lithography or etching. Thus, when L, X, and M are determined, θ that minimizes the cell area is obtained. Thus, it is desired that the Si pillars 23a to 23d be disposed such that θ takes a value that minimizes the cell area or a value close thereto. The positional relationship between the Si pillars 23a and 23c in plan view is as follows: the Si pillars 23a and 23c are disposed such that the vertical section of the Si pillar 23a along the line X1-X1′ passing through the center points of the Si pillars 23a and 23b, and the vertical section of the Si pillar 23c along the line X2-X2′ passing through the center points of the Si pillars 23c and 23d partially overlap each other as viewed from the direction of FIG. 5B. The same applies to the positional relationship between the Si pillars 23b and 23d.

In FIG. 1, the length in the vertical direction of the first gate conductor layer 5a connected to the plate line PL is longer than the length in the vertical direction of the second gate conductor layer 5b connected to the word line WL, so that C_{PL}>C_{WL} holds. However, only adding of the plate line PL decreases a coupling ratio (C_{WL}/(C_{PL}+C_{WL} C_{BL}+C_{SL})) of the capacitive coupling of the word line WL to the channel region 7. As a result, the potential variation ΔV_{FB} of the channel region 7 of the floating body reduces.

In FIGS. 1, 5A, and 5B, the Si pillars 2 and 23a to 23d may have a horizontal sectional shape that is circular, elliptical, or rectangular, so as to perform the dynamic flash memory operation described in the present embodiment. Circular, elliptical, and rectangular dynamic flash memory cells may be disposed together on the same chip.

An air gap or a low-permittivity layer may be provided between the first gate conductor layers 28a and 28b and between the second gate conductor layers 29a and 29b in FIGS. 5A and 5B. The air gap or the low-permittivity layer may be provided only between the second gate conductor layers 29a and 29b.

The distance Z between the first gate conductor layers 28a and 28b and between the second gate conductor layers 29a and 29b in plan view in FIGS. 5A and 5B is made larger than the larger one of the thickness in the vertical direction of the first gate conductor layers 28a and 28b and the thickness in the vertical direction of the second gate conductor layers 29a and 29b. This makes it possible to form dummy material layers of the first gate conductor layers 28a and 28b and the second gate conductor layers 29a and 29b, remove the dummy material layers, and then apply gate conductor layer material layers, so as to form the first gate conductor layers 28a and 28b and the second gate conductor layers 29a and 29b that are uniform.

Either or both of the first gate conductor layer 5a and the second gate conductor layer 5b in FIG. 1 may be divided into two or more portions in plan view, and the individual portions may be operated synchronously or asynchronously as conductor electrodes of a plate line and a word line. Accordingly, a dynamic flash memory operation can be performed.

In FIG. 1, either or both of the first gate conductor layer 5a and the second gate conductor layer 5b may be divided into a plurality of gate conductor layers in the vertical direction. The plurality of gate conductor layers obtained by dividing the first gate conductor layer 5a and/or the second gate conductor layer 5b may have the same length in the vertical direction. The plurality of gate conductor layers obtained by dividing the first gate conductor layer 5a and/or the second gate conductor layer 5b may be adjacent to each other in a direction in which the Si pillar 2 extends, or may be provided so as to sandwich another gate conductor layer. The plurality of gate conductor layers may be operated synchronously or asynchronously. Accordingly, a dynamic flash memory operation can be performed. The same applies to the embodiment illustrated in FIGS. 5A and 5B.

The present embodiment provides the following features.

### Feature 1

At the time of a write operation and a read operation in the operation of the dynamic flash memory cell according to the first embodiment of the present invention, the voltage of the word line WL oscillates up and down. At this time, the plate line PL functions to reduce the capacitive coupling ratio between the word line WL and the channel region 7. As a result, when the voltage of the word line WL oscillates up and down, an influence of the voltage change in the channel region 7 can be significantly reduced. This makes it possible to increase the difference in the threshold voltage of the MOS transistor region of the word line WL indicating the logic “0” and “1”. This leads to an increase in the operation margin of the dynamic flash memory cell.

### Feature 2

As illustrated in FIGS. 5A and 5B, the positional relationship in plan view between the Si pillars 23a and 23c surrounded by the first gate conductor layer 28a connected to the plate line PL1 and the second gate conductor layer 29a connected to the word line WL1 is as follows: the Si pillars 23a and 23c are disposed such that the vertical section of the Si pillar 23a along the line X1-X1′ and the vertical section of the Si pillar 23c along the line X2-X2′ partially overlap each other as viewed from the direction of FIG. 5B. The same applies to the positional relationship between the Si pillars 23b and 23d that are surrounded by the first gate conductor layer 28b connected to the plate line PL2 and the second gate conductor layer 29b connected to the word line WL2 and that stand apart from the Si pillars 23a and 23c. Accordingly, the memory cell area in the direction of the line X1-X1′ and the line X2-X2′ can be effectively reduced, and thus the dynamic flash memory cells can be highly integrated.

### Feature 3

In FIGS. 5A and 5B, in the disposition of the Si pillars 23a to 23d in plan view, a region between first intersection points between the line X1-X1′ passing through the center points of the Si pillars 23a and 23b standing apart from each other and the outer periphery line of the Si pillar 23a, and a region between second intersection points between the line X2-X2′ passing through the center points of the Si pillars 23c and 23d and the outer periphery line of the Si pillar 23c overlap each other when the section in FIG. 5B is viewed in projection. Alternatively, the Si pillars 23a and 23c may be disposed such that the vertical section of the Si pillar 23a along the line Y1-Y1′ orthogonal to the line X1-X1′ passing through the center point of the Si pillar 23a, and the vertical section of the Si pillar 23c along the line Y2-Y2′ partially overlap each other as viewed from the direction of FIG. 5B. In this case, the memory cell area can be effectively reduced in the direction of the line Y1-1′ and the line Y2-Y2′. Accordingly, the dynamic flash memory cells can be highly integrated.

### Second Embodiment

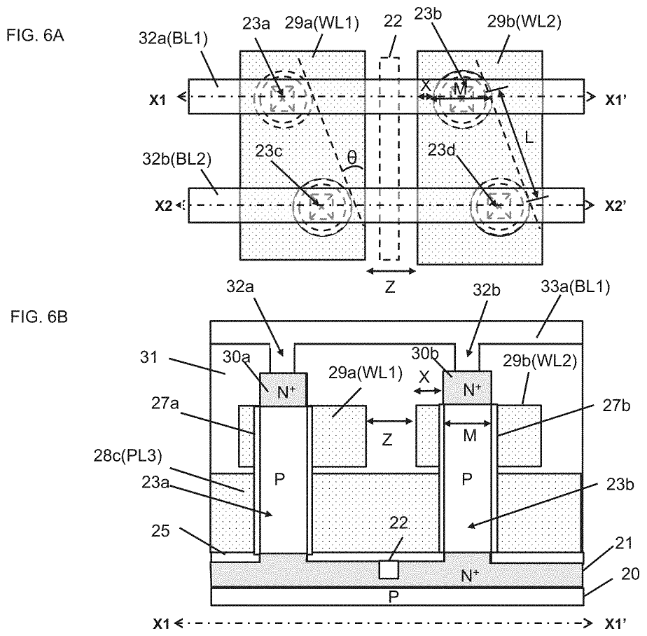

A dynamic flash memory of a second embodiment will be described with reference to FIGS. 6A and 6B. FIG. 6A is a plan view, and FIG. 6B is a sectional view taken along the line X1-X1′ in FIG. 6A. In an actual dynamic flash memory, many memory cells are arranged two-dimensionally.

In FIGS. 5A and 5B, the plate line PL1 is connected to the first gate conductor layer 28a, and the plate line PL2 is connected to the first gate conductor layer 28b. In contrast, in the present embodiment, the first gate conductor layers 28a and 28b isolated from each other in FIGS. 5A and 5B are combined to form a third gate conductor layer 28c, as illustrated in FIG. 6B. The third gate conductor layer 28c is connected to a plate line PL3. The third gate conductor layers 28c of individual memory cells are operated at the same driving voltage, and thereby an operation of the dynamic flash memory is performed.

In the present embodiment, it is not necessary to separately form the first gate conductor layers 28a and 28b in the memory cell illustrated in FIGS. 5A and 5B. Accordingly, the dynamic flash memory can be easily manufactured.

### Third Embodiment

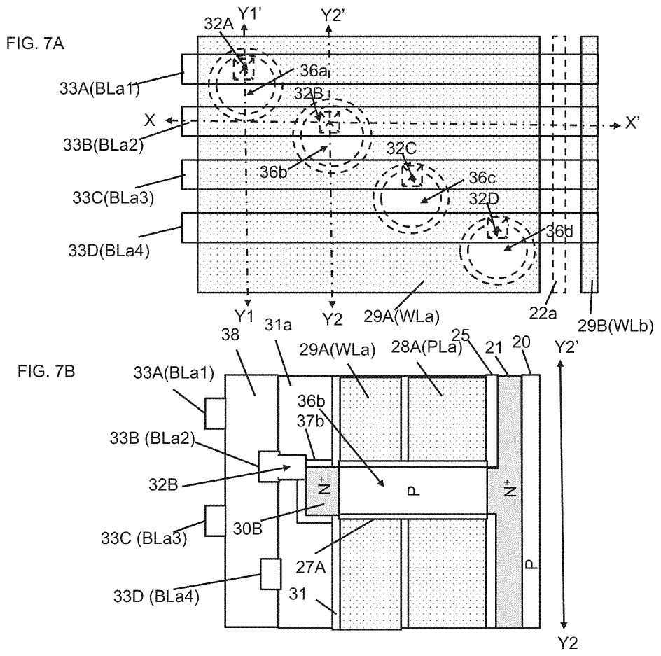

A dynamic flash memory of a third embodiment will be described with reference to FIGS. 7A and 7B. FIG. 7A is a plan view, and FIG. 7B is a sectional view taken along the line Y2-Y2′ in FIG. 7A. In an actual dynamic flash memory, many memory cells are arranged two-dimensionally.

As illustrated in FIG. 7A, Si pillars 36a, 36b, 36c, and 36d are formed so as to be displaced from each other in an oblique direction with respect to the directions of the line X-X′ and the line Y2-Y2′, which are perpendicular to each other in plan view. A gate insulating layer 27A surrounds each of the Si pillars 36a to 36d. A first gate conductor layer 28A surrounding the gate insulating layer 27A of each Si pillar is disposed around lower portions of the Si pillars 36a to 36d. A second gate conductor layer 29A surrounding the gate insulating layer 27A is disposed around upper portions of the Si pillars 36a to 36d. An N⁺ layer 30A (not illustrated), an N⁺ layer 30B, an N⁺ layer 30C (not illustrated), and an N⁺ layer 30D (not illustrated) are disposed at top portions of the Si pillars 36a to 36d, respectively. A silicon nitride (SiN) layer 31 covers the upper surface of the second gate conductor layer 29A in outer periphery portions of the N⁺ layers 30A to 30D. A metal layer 37a (not illustrated), a metal layer 37b, a metal layer 37c (not illustrated), and a metal layer 37d (not illustrated) cover the N⁺ layers 30A to 30D, respectively. A SiO₂ layer 31a covers the entirety. Wiring metal layers 33B and 33D extend in the direction of the line X-X′ and are connected via contact holes 32B and 32D in the SiO₂ layer 31a on the metal layers 37b and 37d. An insulating layer 38 covers the entirety. Wiring metal layers 33A and 33C extend in the direction of the line X-X′ and are connected to the metal layers 37a and 37c (not illustrated) via contact holes 32A and 32C. The first gate conductor layer 28A is connected to a plate line PLa, the second gate conductor layer 29A is connected to a word line WLa, and the wiring metal layers 33A to 33D are connected to bit lines BLa1 to BLa4. In plan view, the wiring metal layer 33B overlaps the metal layers 37a and 37b, the wiring metal layer 33C overlaps the metal layers 37b and 37c, and the wiring metal layer 33D overlaps the metal layers 37c and 37d.

In FIG. 7A, two sections of the Si pillars 36a and 36b, in which the line Y1-Y1′ and the line Y2-Y2′ passing through the center points of the Si pillars 36a and 36b cross the outer periphery lines of the Si pillars 36a and 36b, are formed so as to overlap each other when the section in FIG. 7B is viewed in projection. This relationship is the same also between the Si pillars 36b and 36c and between the Si pillars 36c and 36d.

In FIG. 7A, the center points of the contact holes 32A to 32D are located apart from the center points of the Si pillars 36a to 36d, respectively. Alternatively, the center points of the contact holes 32A to 32D may be located at the center points of the Si pillars 36a to 36d, respectively. In this case, the diameters of the Si pillars 36a to 36d may be increased so that the wiring metal layer 33B overlaps the metal layers 37a and 37b, the wiring metal layer 33C overlaps the metal layers 37b and 37c, and the wiring metal layer 33D overlaps the metal layers 37c and 37d in plan view. For example, in the vertical direction, the lower surface positions of the wiring metal layers 33A and 33C extending in the horizontal direction may be higher than the upper surface positions of the wiring metal layers 33B and 33D extending in the horizontal direction.

Although a description is given in the present embodiment of a case in which the four Si pillars 36a to 36d are formed within the widths of the first gate conductor layer 28A and the second gate conductor layer 29A in the direction of the line X-X′ in plan view, five or more Si pillars may be arranged in the direction of the line connecting the center points of the Si pillars 36a to 36d.

The metal layers 37a to 37d covering the N⁺ layers 30A to 30D may be formed so as to surround only the upper portions or side surfaces of the N⁺ layers 30A to 30D. Also in this configuration, when at least part of each of the contact holes 32A to 32D overlaps the corresponding one of the metal layers 37a to 37d in a plan view, the voltages of the bit lines BLa1 to BLa4 are uniformly applied to the N⁺ layers 30A to 30D. Alternatively, N⁺ layers containing donor impurities may be formed by using, for example, a selective epitaxial crystal growth method so as to cover the N⁺ layers 30A to 30D.

The metal layers 37a to 37d may each be formed of a single layer or a plurality of layers. An alloy layer of silicide or the like may be used. A silicide or metal layer may be provided inside the outer periphery of each of the N⁺ layers 30A to 30D.

The arrangement of the Si pillars 36a to 36d in plan view may have a honeycomb pattern, a zigzag pattern, a sawtooth pattern, or the like. In this case, one bit-line wiring line overlaps the wiring metal layers corresponding to the metal layers 37a to 37d of an adjacent cell in plan view.

The present embodiment provides the following features.

### Feature 1

In the present embodiment, the wiring metal layer 33B overlaps the Si pillars 36a and 36b, the wiring metal layer 33C overlaps the Si pillars 36b and 36c, and the wiring metal layer 33D overlaps the Si pillars 36c and 36d in plan view. Accordingly, the distance between memory cells in the direction of the line Y1-Y1′ and the line Y2-Y2′ can be shortened. Accordingly, the dynamic flash memory can be highly integrated.

### Feature 2

The metal layers 37a to 37d covering the N⁺ layers 30A to 30D or surrounding at least the upper surfaces or side surfaces of the N⁺ layers 30A to 30D are provided. The contact holes 32A to 32D that are in contact with the metal layers 37a to 37d are provided above or below the center points of the Si pillars 36a to 36d in the direction of the line Y1-Y1′ and the line Y2-Y2′ in plan view. Accordingly, as long as the contact holes 32A to 32D are in contact with the metal layers 37a to 37d, the voltages applied to the bit lines BLa1 to BLa4 are uniformly applied to the N⁺ layers 30A to 30D. Accordingly, higher density and higher performance of the dynamic flash memory can be achieved.

### Fourth Embodiment

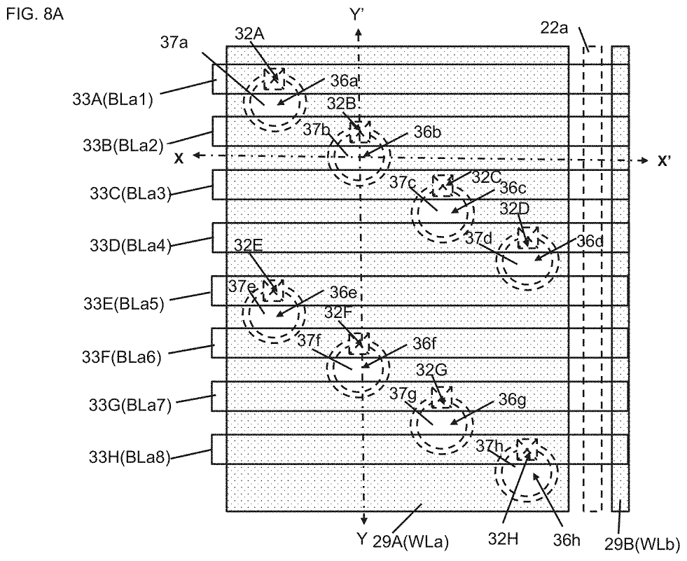

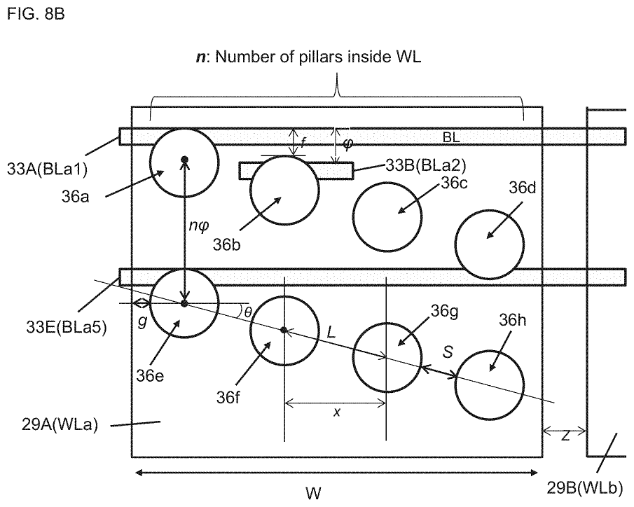

A dynamic flash memory of a fourth embodiment will be described with reference to FIGS. 8A and 8B. FIG. 8A is a plan view of arranged memory cells. FIG. 8B is a schematic plan view for easy understanding of the arrangement relationship of the memory cells illustrated in FIG. 8A.

As illustrated in FIG. 8A, the region in which the Si pillars 36a, 36b, 36c, and 36d are arranged is the same as that illustrated in FIG. 7A. In the region in which Si pillars 36e, 36f, 36g, and 36h are arranged, the Si pillars 36e to 36h in the same arrangement as that of the Si pillars 36a to 36d are blow the Si pillars 36a to 36d in the direction of the line Y-Y′. A wiring metal layer 33E is connected to a metal layer 37e of the Si pillar 36e via a contact hole 32E. A wiring metal layer 33F is connected to a metal layer 37f of the Si pillar 36f via a contact hole 32F. A wiring metal layer 33G is connected to a metal layer 37g of the Si pillar 36g via a contact hole 32G. A wiring metal layer 33H is connected to a metal layer 37h of the Si pillar 36h via a contact hole 32H. The wiring metal layer 33E extending in the direction of the line X-X′ overlaps a part of the metal layer 37d and a part of the metal layer 37e in plan view. The wiring metal layer 33F overlaps a part of the metal layer 37e and a part of the metal layer 37f in plan view. The wiring metal layer 33G overlaps a part of the metal layer 37f and a part of the metal layer 37g in plan view. The wiring metal layer 33H overlaps a part of the metal layer 37g and a part of the metal layer 37h in plan view. The wiring metal layers 33E to 33H are connected to bit lines BLa5 to BLa8, respectively.

FIG. 8B is a schematic plan view for easy understanding of the arrangement relationship of the memory cells illustrated in FIG. 8A. The distance between the center points of adjacent Si pillars of the Si pillars 36a to 36h is represented by L, the pitch length of the Si pillars 36a to 36h in the direction of the line X-X′ is represented by x, the pitch length of the Si pillars 36a to 36h in the direction of the line Y-Y′ is represented by nϕ, the shortest distance between the outer periphery lines of adjacent Si pillars is represented by S, the pitch length between bit line wiring metal layers is represented by ϕ, a view angle formed by the line X-X′ and the straight line connecting the centers of the Si pillars 36a to 36d or the Si pillars 36e to 36h is represented by θ, the shortest distance along the line X-X′ between the outer periphery line of the Si pillar 36a or 36e and the second gate conductor layer 29A is represented by g, the shortest distance in the direction of the line Y-Y′ between the upper end of the wiring metal layer 33A and the outer periphery line of the Si pillar 36b is represented by f, the width in the direction of the line X-X′ of the second gate conductor layer 29A connected to the word line WLa is represented by W, the distance between the second gate conductor layer 29B connected to the word line WLb and the second gate conductor layer 29A is represented by Z, the diameter of each of the Si pillars 36a to 36h is represented by H, the number of the Si pillars 36a to 36h within the word line WL in the horizontal direction is represented by n (four in FIGS. 8A and 8B), the pitch of the Si pillars 36a to 36h in the horizontal direction is represented by X, and the pitch of the word line WL in the horizontal direction is represented by WLpitch. In this case, the following relationships are obtained.

L=H+S (6)

X=L cos θ (7)

W=(n−1)L cos θ+H+2g (8)

WLpitch=W+Z (9)

f=L sin θ≥ϕ (10)

Accordingly, an effective cell area SS is expressed by the following equation.

SS=(W+Z)ϕ/n (11)

Here, x, nϕ, S, ϕ, f, W, H, and g are determined by minimum values, accuracy, and so forth in a process such as lithography or etching. Thus, when these values are determined, θ that minimizes the cell area is obtained. Thus, it is desired that the Si pillars 36a to 36h be arranged such that θ is close to a value that minimizes the cell area.

The present embodiment provides the following feature.

### Feature 1

In the present embodiment, the arrangement of the Si pillars 36a to 36h, the contact holes 32A to 32H, and the wiring metal layers 33A to 33H connected to the bit lines BLa1 to BLa8 corresponds to the relationship in which two memory blocks, each illustrated in FIGS. 7A and 7B, are connected to each other in the direction of the line Y-Y′. As a result of increasing the number of memory blocks, the number of the Si pillars 36a to 36h connected to the second gate conductor layer 29A connected to one word line WLa can be increased, with the high density of memory cells maintained.

### Fifth Embodiment

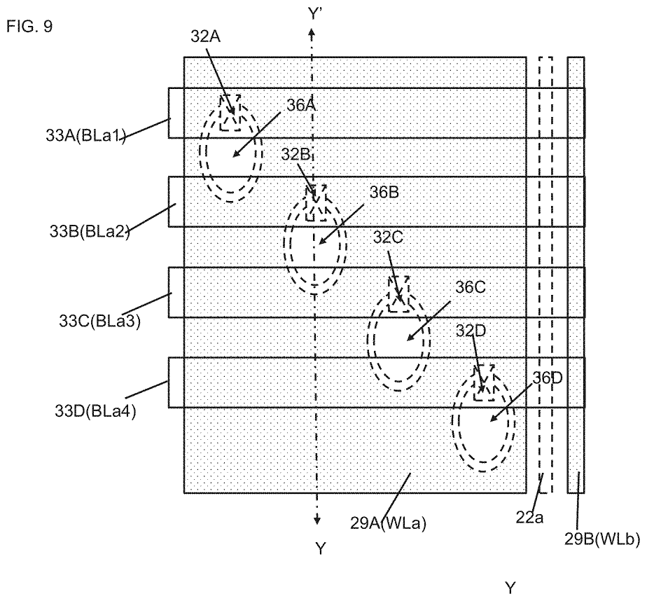

A dynamic flash memory of a fifth embodiment will be described with reference to the plan view of a memory cell block in FIG. 9. In an actual dynamic flash memory, many memory cells are arranged two-dimensionally.

While the shapes of the Si pillars 36a to 36d in plan view in FIG. 7A are circular, Si pillars 36A to 36D in the present embodiment have an elliptical or rectangular shape extending in the direction of the line Y-Y′ as illustrated in FIG. 9. The others are the same as in FIGS. 7A and 7B.

In the present embodiment, the Si pillars 36A to 36D have an elliptical shape or a rectangular shape extending in the direction of the line Y-Y′, and thus the distances between the wiring metal layers 33A to 33D connected to the bit lines BLa1 to BLa4 can be increased, or the lengths of the contact holes 32A to 32D in the direction of the line Y-Y′ can be increased. Accordingly, the degree of freedom in designing highly integrated memory cells can be increased.

### OTHER EMBODIMENTS

Although the Si pillars 2, 23a to 23d, 36a to 36h, and 36A to 36D are formed in the above embodiments, semiconductor pillars made of a semiconductor material other than Si may be used. The same applies to other embodiments according to the present invention.

The Si pillars 23a to 23d in FIGS. 5A and 5B may be formed by forming a single-crystal Si layer connected to the entire upper surface of the N⁺ layer 21 and then using a lithography method and a reactive ion etching (RIE) method. The Si pillars 23a to 23d may be formed by, after forming conductor layers serving as the first gate conductor layers 28a and 28b and the second gate conductor layers 29a and 29b or a dummy layer, forming holes in the P-layer substrate 20 in the vertical direction by using the lithography method and the RIE method, and forming the Si pillars 23a to 23d in the holes by using, for example, an epitaxial crystal growth method. The Si pillars 23a to 23d may be formed by using another method. The same applies to other embodiments according to the present invention.

The N⁺ layers 3a, 3b, 21, and 30a to 30d in the first embodiment may be formed of layers made of Si containing donor impurities or another semiconductor material. Alternatively, the N⁺ layers 3a, 3b, 21, and 30a to 30d may be formed of layers made of different semiconductor materials. The N⁺ layers may be formed by an epitaxial crystal growth method or another method. The substrate 1 and the P-layer substrate 20 may each be a semiconductor layer, an insulating layer, a conductor layer such as a metal layer, or a well layer formed of a PNP layer. The same applies to other embodiments according to the present invention.

The first gate conductor layers 28a and 28b and the second gate conductor layers 29a and 29b illustrated in FIGS. 5A and 5B may be formed of a single layer or a combination of a plurality of conductor material layers. The same applies to other embodiments according to the present invention.

Although the gate insulating layers 27a to 27d in FIGS. 5A and 5B are formed so as to be isolated from each other between the Si pillars 23a to 23d, the gate insulating layers 27a to 27d may be formed so as to be connected to each other on the SiO₂ layer 25. The gate insulating layers 27a to 27d may be formed so as to be isolated from each other, like the first gate insulating layer 4a and the second gate insulating layer 4b in FIG. 1. The same applies to other embodiments according to the present invention.

In FIG. 1, the gate length of the first gate conductor layer 5a is made longer than the gate length of the second gate conductor layer 5b so that the gate capacitance of the first gate conductor layer 5a connected to the plate line PL is larger than the gate capacitance of the second gate conductor layer 5b connected to the word line WL. Alternatively, instead of making the gate length of the first gate conductor layer 5a longer than the gate length of the second gate conductor layer 5b, the gate insulating film of the first gate insulating layer 4a may be made thinner than the gate insulating film of the second gate insulating layer 4b by changing the film thicknesses of the respective gate insulating layers. The permittivity of the gate insulating film of the first gate insulating layer 4a may be made higher than the permittivity of the gate insulating film of the second gate insulating layer 4b by changing the permittivities of the materials of the respective gate insulating layers. The gate capacitance of the first gate conductor layer 5a connected to the plate line PL may be made larger than the gate capacitance of the second gate conductor layer 5b connected to the word line WL by combining the lengths of the gate conductor layers 5a and 5b and the film thicknesses or permittivities of the gate insulating layers 4a and 4b. The first gate conductor layer 5a may be divided into a plurality of portions in the vertical direction so that the gate capacitance of the first gate conductor layer 5a is larger than the gate capacitance of the second gate conductor layer 5b. The same applies to other embodiments according to the present invention.

In the first embodiment, the shapes of the Si pillars 23a to 23d in plan view are circular, but the shapes of the Si pillars 23a to 23d in plan view may be circular, elliptical, a shape elongated in one direction, or the like. Also in a logic circuit region formed apart from the dynamic flash memory cell region, Si pillars having different shapes in plan view may be formed together in the logic circuit region in accordance with logic circuit design. The same applies to other embodiments according to the present invention.

In the first embodiment, the source line SL is negatively biased to discharge the hole group in the channel region 7 serving as the floating body FB during an erase operation. Alternatively, the bit line BL may be negatively biased, or the source line SL and the bit line BL may be negatively biased, instead of the source line SL, to perform an erase operation. Alternatively, an erase operation may be performed under another voltage condition. The same applies to other embodiments according to the present invention.

The W layer 22 connected to the N⁺ layer 21 illustrated in FIGS. 5A and 5B may be replaced with another conductor material layer. A conductor layer, such as a W layer, may be formed in the N⁺ layer 21 outside the region in which more Si pillars 23a to 23d are arranged two dimensionally. A conductor layer, such as a W layer, may be formed on the entire surface or the entire bottom surface of the P layer 20. The same applies to other embodiments according to the present invention.

In the present invention, various embodiments and modifications can be made without departing from the broad spirit and scope of the present invention. The above-described embodiments are for explaining an example of the present invention, and do not limit the scope of the present invention. The above-described embodiments and modifications can be combined as appropriate. Furthermore, the above-described embodiments from which one or some of constituent elements are removed as appropriate are also within the scope of the technical idea of the present invention.

According to the semiconductor memory device of the present invention, a high-density and high-performance dynamic flash memory can be obtained.

What is claimed is:

1. A semiconductor memory device comprising:
a first impurity layer disposed on a substrate;
a first semiconductor pillar and a second semiconductor pillar that are adjacent to each other on the first impurity layer and that stand in a vertical direction with respect to the substrate;
a second impurity layer disposed at a top portion of the first semiconductor pillar, and a third impurity layer disposed at a top portion of the second semiconductor pillar;
a first gate insulating layer surrounding lower side surfaces of the first semiconductor pillar and the second semiconductor pillar, and a second gate insulating layer surrounding upper side surfaces of the first semiconductor pillar and the second semiconductor pillar;
a first gate conductor layer surrounding a side surface of the first gate insulating layer; and
a second gate conductor layer surrounding a side surface of the second gate insulating layer, wherein
in plan view, a midpoint of the first semiconductor pillar and a midpoint of the second semiconductor pillar in a first direction are displaced from each other in a second direction orthogonal to the first direction or in the first direction,
a vertical section of the first semiconductor pillar and a vertical section of the second semiconductor pillar in the first direction or the second direction partially overlap each other in perspective view in a vertical section direction,
the semiconductor memory device further comprises:
a first conductor layer made of a metal or an alloy and covering a part or an entirety of the second impurity layer at the top portion of the first semiconductor pillar, and a second conductor layer made of a metal or an alloy and covering a part or an entirety of the third impurity layer at the top portion of the second semiconductor pillar;
a first contact hole that is in contact with the first conductor layer in plan view, and a second contact hole that is in contact with the second conductor layer in plan view; and
a first wiring metal layer connected to the first conductor layer via the first contact hole and extending in the second direction, and a second wiring metal layer connected to the second conductor layer via the second contact hole and extending in the second direction,
the second wiring metal layer overlaps a part of the first conductor layer and a part of the second conductor layer in plan view, and
the semiconductor memory device is configured to perform
a data write operation and a data hold operation of holding, in an inside of the first semiconductor pillar and the second semiconductor pillar, holes or electrons generated by an impact ionization phenomenon or a gate-induced drain-leakage current, by applying a voltage to the first impurity layer, the second impurity layer, the third impurity layer, the first gate conductor layer, and the second gate conductor layer, and
a data erase operation of discharging the held holes or electrons from the inside of the first semiconductor pillar and the second semiconductor pillar by applying a voltage to the first impurity layer, the second impurity layer, the third impurity layer, the first gate conductor layer, and the second gate conductor layer.

2. The semiconductor memory device according to claim 1, wherein
the first impurity layer is connected to a source line whereas the second impurity layer and the third impurity layer are connected to a bit line, or
the first impurity layer is connected to the bit line whereas the second impurity layer and the third impurity layer are connected to the source line.

3. The semiconductor memory device according to claim 1, wherein
the first gate conductor layer is connected to a plate line whereas the second gate conductor layer is connected to a word line, or
the first gate conductor layer is connected to the word line whereas the second gate conductor layer is connected to the plate line.

4. The semiconductor memory device according to claim 1, wherein
in semiconductor pillar groups which are in a memory region and each of which includes the first semiconductor pillar and the second semiconductor pillar on the substrate, the first gate conductor layer surrounding the first semiconductor pillar and the second semiconductor pillar is continuous between the semiconductor pillar groups in plan view.

5. The semiconductor memory device according to claim 1, wherein
in semiconductor pillar groups which are in a memory region and each of which includes the first semiconductor pillar and the second semiconductor pillar on the substrate, the first gate conductor layer surrounding the first semiconductor pillar and the second semiconductor pillar and the second gate conductor layer surrounding the first semiconductor pillar and the second semiconductor pillar are each continuous between the semiconductor pillar groups in plan view.

6. The semiconductor memory device according to claim 1, wherein
the first contact hole has a center point displaced from a center point of the first semiconductor pillar in the first direction and is in contact with the first conductor layer in plan view, and
the second contact hole has a center point displaced from a center point of the second semiconductor pillar in the first direction and is in contact with the second conductor layer in plan view.

7. The semiconductor memory device according to claim 1, wherein
in the vertical direction, an upper end of the first contact hole is above an upper end of the second contact hole, and a bottom surface of the first wiring metal layer extending in a horizontal direction is above an upper surface of the second wiring metal layer extending in the horizontal direction.

8. The semiconductor memory device according to claim 1, wherein
in the vertical direction, the first wiring metal layer and the second wiring metal layer are at different heights.

9. The semiconductor memory device according to claim 1, further comprising:
one or more third semiconductor pillars each of which has a center point on a first line connecting a center point of the first semiconductor pillar and a center point of the second semiconductor pillar and which are arranged at an equal pitch in a length between the center point of the first semiconductor pillar and the center point of the second semiconductor pillar in plan view, wherein
the first gate insulating layer surrounds lower portions of the first semiconductor pillar, the second semiconductor pillar, and the one or more third semiconductor pillars,
the second gate insulating layer surrounds upper portions of the first semiconductor pillar, the second semiconductor pillar, and the one or more third semiconductor pillars,
the first gate conductor layer covers the first gate insulating layer, and
the second gate conductor layer covers the second gate insulating layer.

10. The semiconductor memory device according to claim 9, wherein
in plan view, two or more block regions, each including the first semiconductor pillar, the second semiconductor pillar, and the one or more third semiconductor pillars, are connected to each other and provided in a direction in which the second gate conductor layer extends, and
in plan view, the first wiring metal layer is disposed above the first conductor layer on the top portion of the first semiconductor pillar and above a third conductor layer on the top portion of the one or more third semiconductor pillars at an end of an adjacent block region.

11. The semiconductor memory device according to claim 1, wherein
in plan view, a distance between the second gate conductor layer and a fourth gate conductor layer that is adjacent to the second gate conductor layer and connected to a second word line is larger than a half of a larger one of a thickness of the first gate conductor layer and a thickness of the second gate conductor layer.

12. The semiconductor memory device according to claim 1, wherein
the first impurity layer outside the first semiconductor pillar and the second semiconductor pillar has therein a metal layer or an alloy layer in plan view.

13. The semiconductor memory device according to claim 1, wherein
a first gate capacitance between the first gate conductor layer and the first semiconductor pillar is larger than a second gate capacitance between the second gate conductor layer and the first semiconductor pillar.

14. The semiconductor memory device according to claim 1, wherein
one or both of the first gate conductor layer and the second gate conductor layer are divided into a plurality of gate conductor layers in the vertical direction, the plurality of gate conductor layers being configured to be driven synchronously or asynchronously.
